(19) United States
(12) Patent Application Publication
(10) Pub. No.: US 2025/0244088 A1
(43) Pub. Date: Jul. 31, 2025

(54) PIEZOELECTRIC HEAT DISSIPATION DEVICE AND ELECTRONIC DEVICE

(71) Applicant: REALMAGIC SEMICONDUCTORS (SHENZHEN) CO., LTD., Guangdong (CN)

(72) Inventors: Lei Tang, Guangdong (CN); Bo He, Guangdong (CN); Qingsong Yang, Guangdong (CN)

(21) Appl. No.: 18/999,289

(22) Filed: Dec. 23, 2024

(30) Foreign Application Priority Data
Jan. 29, 2024 (CN) 202420205364.2
May 15, 2024 (CN) 202421048512.0

(51) Int. Cl. F28F 9/00; H10N 30/20; H10N 30/80; H10N 30/88

(52) U.S. Cl. CPC F28F 9/005; H10N 30/2047; H10N 30/802; H10N 30/88

(57) ABSTRACT

A piezoelectric heat dissipation device and an electronic device; the piezoelectric heat dissipation device includes a housing, the housing has an accommodation cavity, the housing is provided with an air inlet and an air outlet being opposite to the air inlet; an elastic sheet, where the elastic sheet is accommodated in the accommodation cavity, and two opposite ends of the elastic sheet are respectively connected to the housing; the elastic sheet has a vibration center line; a piezoelectric ceramic member fixedly connected to the elastic sheet, where a projection of the piezoelectric ceramic member does not overlap with a projection of the vibration center line in a thickness direction of the elastic sheet; and an electric control member electrically connected with the piezoelectric ceramic member and configured to supply power to the piezoelectric ceramic member.

### CROSS-REFERENCE TO RELATED APPLICATION

This application claims priority to Chinese patent application No. 202420205364.2, filed on Jan. 29, 2024, and entitled “air pump for heat dissipation, and electronic device”, and claims priority to Chinese patent application No. 202421048512.0, filed on May 15, 2024, and entitled “piezoelectric heat dissipation device and electronic device”. The entire contents each of which are incorporated herein by reference.

### TECHNICAL FIELD

The present disclosure relates to the field of electronic device technologies, and more particularly, to a piezoelectric heat dissipation device and an electronic device.

### BACKGROUND

With the miniaturization development trend of electronic products such as mobile phones and computers, a heat dissipation difficulty of a core component (e.g., an integrated chip, a central processing unit, etc.) is also increased gradually, due to the limitation of size, it is always difficult for traditional fan heat dissipation to meet the heat dissipation requirements of electronic products. Piezoelectric ceramic is a ceramic material having a piezoelectric effect, and may be stretched and deformed when applying an electric field to two ends of the piezoelectric ceramic, and the size of the piezoelectric ceramic may be smaller. By connecting the piezoelectric ceramic to a metal piece, the metal piece may be driven to vibrate when an electric field is applied to the piezoelectric ceramic, and air in the space of the piezoelectric ceramic is driven to flow accordingly. Therefore, the piezoelectric ceramic starts to be applied to heat dissipation of the electronic product gradually.

In the related art, when the piezoelectric ceramic is used to dissipate heat of the electronic product, the entire piezoelectric ceramic is completely attached to a vibration region of the metal sheet. When the metal piece vibrates up and down, a large bending deformation of the vibration region is generated, and the entire piezoelectric ceramic is driven by the metal sheet to generate bending with large deformation synchronously. Due to low toughness of the piezoelectric ceramic, the piezoelectric ceramic is prone to failure and have low heat dissipation reliability during the process of bending up and down of the entire piezoelectric ceramic.

### SUMMARY

An objective of the embodiments of the present disclosure is to provide a piezoelectric heat dissipation device and an electronic device, which are directed at solving the technical problem in the related art that a piezoelectric ceramic is prone to failure and has low heat dissipation reliability during the process of bending up and down of the piezoelectric ceramic.

In order to achieve the aforesaid objective, the technical solutions adopted in the present disclosure is providing a piezoelectric heat dissipation device, including:
a housing, where the housing has an accommodation cavity and is provided with an air inlet and an air outlet;
an elastic sheet, where the elastic sheet is accommodated in the accommodating cavity, and two opposite ends of the elastic sheet are respectively connected to the housing; the elastic sheet separates the accommodating cavity into a first accommodation sub-cavity and a second accommodation sub-cavity, the first accommodation sub-cavity is communicated with the air outlet, the elastic sheet is provided with a plurality of first nozzles that correspond to the air outlet, and the elastic sheet has a vibration center line;
a piezoelectric ceramic member, where the piezoelectric ceramic member is fixedly connected to the elastic sheet, and a projection of the piezoelectric ceramic member does not overlap with a projection of the vibration center line in a thickness direction of the elastic sheet; and
an electric control member electrically connected to the piezoelectric ceramic member, where the electric control member is configured to supply power to the piezoelectric ceramic member.

According to the piezoelectric heat dissipation device provided in this embodiment of the present disclosure, the electric control member supplies power to the piezoelectric ceramic member, to enable the piezoelectric ceramic member to be driven to be stretched and deformed, and a main part of the elastic sheet is driven by the piezoelectric ceramic member to bend up and down to vibrate, such that air in the first accommodation sub-cavity and the second accommodation sub-cavity flows therethrough, and the air in the accommodation cavity is discharged from the air outlet, and new air is supplied from the air inlet simultaneously to achieve the purpose of heat dissipation. By adopting the vibration principle of the piezoelectric ceramic member and the elastic sheet, a more miniaturized design may be realized, a possibility of micro-miniature development trend of the electronic product is provided, and a heat dissipation noise is small, and better user experience may be provided.

In some embodiments, the elastic sheet has a symmetrical structure, the elastic sheet includes a main part and a fixing part disposed at two opposite ends of the main part. The fixing part is connected to the housing, and a thickness of the main part is less than a thickness of the fixing part. The main part is provided with the plurality of first nozzles, and the vibration center line is an axis of symmetry of the main part.

By adopting the aforesaid technical solution, since the thickness of the main part is less than the thickness of the fixing part, when the elastic sheet is stressed, the region of the vibration center line of the main part has a maximum bending deformation amount, the bending deformation amount of other regions is small, and the projection of the piezoelectric ceramic member does not overlap with the projection of the vibration center line of the main part in the thickness direction of the elastic sheet, thus, the overall bending deformation amount of the piezoelectric ceramic member is small in the bending and deforming process of the main part, which is conducive to reducing the possibility of failure of the piezoelectric ceramic and improving the reliability of the piezoelectric heat dissipation device.

In some embodiments, in the thickness direction of the elastic sheet, the projection of the piezoelectric ceramic member does not overlap with projections of the plurality of first nozzles; or alternatively,
in the thickness direction of the elastic sheet, the projection of the piezoelectric ceramic member overlaps with the projections of the plurality of first nozzles.

By adopting the aforesaid technical solution, when the projection of the piezoelectric ceramic member does not overlap with the projections of the first nozzles, the piezoelectric ceramic member and the plurality of first nozzles are staggered, the piezoelectric ceramic member does not block the first nozzles, and a hole does not need to be formed on the piezoelectric ceramic member, which is conducive to improving the reliability of the piezoelectric ceramic member and improving the reliability of the piezoelectric heat dissipation device. When the projection of the piezoelectric ceramic member overlaps with the projections of the first nozzles, a contact area between the piezoelectric ceramic member and the main part may be increased. Thus, the deformation of the piezoelectric ceramic member may be effectively transferred to the main part to drive the main part to bend to be deformed, which is conducive to improving the heat dissipation efficiency of the piezoelectric heat dissipation device.

In some embodiments, in the thickness direction of the elastic sheet, the projection of the piezoelectric ceramic member overlaps with projections of at least a part of the plurality of first nozzles; and the piezoelectric ceramic member is provided with a plurality of second nozzles corresponding to the part of the plurality of first nozzles.

By adopting the aforesaid technical solution, the projection of the piezoelectric ceramic member overlaps with the projections of the part of the plurality of first nozzles, the contact area between the piezoelectric ceramic member and the main part may be increased. Thus, the deformation of the piezoelectric ceramic member may be effectively transferred to the main part to drive the main part to bend to be deformed, which is conducive to improving the heat dissipation efficiency of the piezoelectric heat dissipation device. Moreover, the piezoelectric ceramic member is provided with the second nozzles corresponding to the part of the plurality of first nozzles, the occurrence of condition of blocking the air from entering through the first nozzle or blocking the air from flowing out of the second accommodation sub-cavity by the piezoelectric ceramic member is reduced.

In some embodiments, in the thickness direction of the elastic sheet, the projection of the piezoelectric ceramic member overlaps with a projection of the fixing part; or alternatively,
in the thickness direction of the elastic sheet, the projection of the piezoelectric ceramic member does not overlap with the projection of the fixing part.

By adopting the aforesaid technical solution, when the projection of the piezoelectric ceramic member overlaps with the projection of the fixing part, a part of deformation of the piezoelectric ceramic member is transferred to the fixing part, since the thickness of the fixing part is greater than the thickness of the main part, the bending deformation of the fixing part is less than the bending deformation of the main part, which is conducive to reducing the overall deformation of the piezoelectric ceramic when the elastic sheet is bent to be deformed, reducing the failure of the piezoelectric ceramic member and improving the reliability of the piezoelectric ceramic member. When the projection of the piezoelectric ceramic member does not overlap with the projection of the fixing part, the deformation of the piezoelectric ceramic member may be effectively transferred to the main part to drive the main part to bend to be deformed, which is conducive to improving the heat dissipation effect of the piezoelectric heat dissipation device.

In some embodiments, the elastic sheet further includes a transition part, the transition part has a first end and a second end which are oppositely arranged. The first end is connected to the fixing part, the second end is connected to the main part. In the thickness direction of the elastic sheet, the projection of the piezoelectric ceramic member overlaps with a projection of the fixing part; or alternatively,

In the thickness direction of the elastic sheet, the projection of the piezoelectric ceramic member overlaps with a projection of the transition part, and the projection of the piezoelectric ceramic member does not overlap with the projection of the fixing part; or alternatively,

In the thickness direction of the elastic sheet, the projection of the piezoelectric ceramic member does not overlap with the projection of the transition part.

By adopting the aforesaid technical solution, a transition part is provided between the main part and the fixing part, which is conducive to achieving uniform transition of bending deformation between the main part and the fixing part. Thus, the elastic sheet is stressed more uniformly, which is conducive to improving the reliability of the elastic sheet. When the projection of the piezoelectric ceramic member overlaps with the projection of the fixing part, the overall deformation of the piezoelectric ceramic is reduced, the occurrence of the failure of the piezoelectric ceramic member is reduced, and the reliability of the piezoelectric ceramic member is improved. When the projection of the piezoelectric ceramic member overlaps with the projection of the fixing part and the projection of the piezoelectric ceramic member does not overlap with the projection of the fixing part, the deformation of the piezoelectric ceramic member may be effectively transferred to the main part, thereby driving the main part to bend to be deformed, which is conducive to improving the heat dissipation effect of the piezoelectric heat dissipation device. When the projection of the piezoelectric ceramic member does not overlap with the projection of the transition part, the deformation of the piezoelectric ceramic member may be further effectively transferred to the main part, thereby improving the heat dissipation effect of the piezoelectric heat dissipation device.

In some embodiments, a thickness of the fixing part is greater than a thickness of the transition part, and the thickness of the transition part is greater than a thickness of the main part.

By adopting the aforesaid technical solution, the deformation of the elastic sheet may be gradually transitioned from the main part to the fixing part without generating a stress concentration point at the transition part, such that the stress distribution on the elastic sheet can be more uniform, stress concentration and material fatigue of the elastic sheet may be reduced, the reliability of the elastic sheet and the piezoelectric ceramic member may be improved, and the reliability of the piezoelectric heat dissipation device may be improved.

In some embodiments, a thickness of the transition part is progressively decreased in a direction from the first end to the second end.

By adopting the aforesaid technical solution, the stress concentration and the material fatigue of the elastic sheet may be further reduced, the reliability of the elastic sheet and the piezoelectric ceramic member may be improved, and the reliability of the piezoelectric heat dissipation device may be improved.

In some embodiments, a plurality of piezoelectric ceramic members are provided, and the plurality of piezoelectric ceramic members are symmetrically arranged at two opposite sides of the vibration center line.

By adopting the aforesaid technical solution, the plurality of piezoelectric ceramic parts are symmetrically arranged at two opposite sides of the vibration center line, more uniform vibration and higher vibration amplitude may be achieved, air fluidity between the first accommodation sub-cavity and the second accommodation sub-cavity may be improved, and the heat dissipation effect of the piezoelectric heat dissipation device is improved.

In some embodiments, the air inlet and the air outlet are arranged in a staggered manner, and air in the first accommodation sub-cavity and air in the second accommodation sub-cavity are discharged unidirectionally from the air outlet.

By adopting the aforesaid technical solution, the air inlet and the air outlet are arranged in the staggered manner. Thus, air may be effectively guided to enter from the air inlet and be discharged from the air outlet. A condition that the air entering from the air inlet is directly discharged from the air outlet when the elastic sheet does not vibrate is avoided. The air flows out from the air outlet unidirectionally, thus, after being electrified, air flow always flows out through the air outlet and does not flow back, which is conducive to improving the heat dissipation effect and the heat dissipation efficiency of the piezoelectric heat dissipation device.

In some embodiments, the housing includes a first housing and a second housing covering the first housing, the first housing and the second housing are enclosed to form an accommodating cavity, and the fixing part is connected to the first housing and the second housing.

In some embodiments, the first housing is provided with an air outlet, the second housing is provided with an air inlet, and an orientation of the air inlet is parallel to an orientation of the air outlet.

In some embodiments, the air outlet is provided on the first housing, the air inlet is provided on the second housing, and the orientation of the air inlet is perpendicular to the orientation of the air outlet.

In some embodiments, the air outlet and the air inlet are provided on the first housing, and the orientation of the air inlet is parallel to the orientation of the air outlet. The air inlet includes a first sub-inlet and a second sub-inlet communicated with the first sub-inlet, where the second housing is provided with the first sub-inlet, and the fixing part is provided with the second sub-inlet.

By adopting the aforesaid technical solution, the first housing and the second housing are enclosed to form the accommodating cavity, the first housing and the second housing are covered, thereby facilitating quick disassembly and assembly of the piezoelectric heat dissipation device. The elastic sheet is connected in the accommodating cavity, which is conducive to improving the stability and the compactness of the structure of the piezoelectric heat dissipation device, and reducing the space occupied by the piezoelectric heat dissipation device, the air may enter or be discharged quickly through the air inlet on the first housing or the first sub-inlet on the second housing and the second sub-inlet on the elastic sheet, and in cooperation with the air outlet on the first housing.

An electronic device is further provided in the present disclosure, the electronic device includes a heat dissipation member, and further includes the aforesaid piezoelectric heat dissipation device, where the heat dissipation member is disposed at the air outlet.

In the electronic device provided by the embodiment of the present disclosure, the heat dissipation member is arranged at the air outlet of the piezoelectric heat dissipation device, when the piezoelectric heat dissipation device is in operation, the electric control member supplies power to the piezoelectric ceramic member so as to drive the piezoelectric ceramic member to be stretched and deformed, and the main part of the elastic sheet is driven by the piezoelectric ceramic member to bend and vibrate up and down, thus, the air in the first accommodation sub-cavity and the second accommodation sub-cavity flows, air in the accommodation cavity is discharged from the air outlet, meanwhile, new air is supplied from the air inlet to achieve the purpose of heat dissipation. The thickness of the main part is less than the thickness of the fixing part, when the elastic sheet is stressed, the vibration center line region of the main part has the maximum bending deformation amount, other regions have smaller bending deformation amount. In the thickness direction of the elastic sheet, the projection of the piezoelectric ceramic member does not overlap with the projection of the vibration center line of the main part. Due to this arrangement, the overall bending deformation amount of the piezoelectric ceramic member is smaller in the bending deformation process of the main part, which is conducive to reducing the possibility of failure of the piezoelectric ceramic and improving the reliability of the piezoelectric heat dissipation device.

The above description is merely summary of the technical solutions of the present disclosure, in order to more clearly understand the technical means of the present disclosure, the technical means of the present disclosure may be implemented according to the contents of the specification, in order to make the above and other objectives, features and advantages of the present disclosure to be more obvious and understandable, the embodiments of the present disclosure are described below.

### DESCRIPTION OF THE DRAWINGS

In order to describe the embodiments of the present disclosure more clearly, a brief introduction regarding the accompanying drawings that need to be used for describing the embodiments of the present disclosure or the associated technologies is given below. It is obvious that the accompanying drawings described below are merely some embodiments of the present disclosure, a person of ordinary skill in the art may also obtain other drawings according to the current drawings without paying creative works.

FIG. 1 is a schematic diagram of an assembled structure of a piezoelectric heat dissipation device according to an embodiment of the present disclosure;

FIG. 2 is a schematic diagram of a cross-sectional structure of the piezoelectric heat dissipation device according to an embodiment of the present disclosure;

FIG. 3 is a schematic diagram of an assembly structure of the piezoelectric heat dissipation device according to an embodiment of the present disclosure;

FIG. 4 is a schematic structural diagram of the piezoelectric heat dissipation device according to an embodiment of the present disclosure;

FIG. 5 is a schematic diagram of an air flow of the piezoelectric heat dissipation device according to one embodiment of the present disclosure;

FIG. 6 is a schematic diagram of an air flow of the piezoelectric heat dissipation device according to another embodiment of the present disclosure;

FIG. 7 is a schematic diagram of a position of the piezoelectric ceramic member according to one embodiment of the present disclosure;

FIG. 8 is a schematic diagram of a position of the piezoelectric ceramic member according to another embodiment of the present disclosure;

FIG. 9 is a schematic diagram of a position of the piezoelectric ceramic member according to another embodiment of the present disclosure;

FIG. 10 is a schematic diagram of a position of the piezoelectric ceramic member according to another embodiment of the present disclosure;

FIG. 11 is a schematic structural diagram of an elastic sheet according to one embodiment of the present disclosure;

FIG. 12 is a schematic diagram of a position of the piezoelectric ceramic member according to another embodiment of the present disclosure;

FIG. 13 is a schematic diagram of a position of the piezoelectric ceramic member according to another embodiment of the present disclosure;

FIG. 14 is a schematic structural diagram of the elastic sheet according to one embodiment of the present disclosure;

FIG. 15 is a schematic structural diagram of the elastic sheet according to one embodiment of the present disclosure;

FIG. 16 is a schematic diagram of an assembled structure of the piezoelectric heat dissipation device according to another embodiment of the present disclosure;

FIG. 17 is a schematic diagram of a cross-sectional structure of the piezoelectric heat dissipation device according to another embodiment of the present disclosure;

FIG. 18 is a schematic diagram of an assembly structure of the piezoelectric heat dissipation device according to another embodiment of the present disclosure;

FIG. 19 is a schematic structural diagram of the piezoelectric heat dissipation device according to one embodiment of the present disclosure;

FIG. 20 is a schematic structural diagram of the piezoelectric heat dissipation device according to another embodiment of the present disclosure;

FIG. 21 is a schematic structural diagram of an electronic device according to one embodiment of the present disclosure; and

FIG. 22 is a schematic structural diagram of the electronic device according to another embodiment of the present disclosure.

### DETAILED DESCRIPTION OF EMBODIMENTS

Embodiments of the present disclosure are described in detail hereinafter, and examples of the embodiment are illustrated in the accompanying figures. Where, an always unchanged reference number or similar reference numbers represent(s) identical or similar components or components having identical or similar functionalities. The embodiment described below with reference to the accompanying figures is for illustrative purpose, is intended to illustrate the present disclosure, but should not be considered as being limitative to the present disclosure.

In the description of the present disclosure, it needs to be understood that, directions or location relationships represented by terms such as “length”, “width”, “up”, “down”, “front”, “rear”, “left”, “right”, “vertical”, “horizontal”, “top”, “bottom”, “inside”, “outside”, etc., are the directions or location relationships shown in the accompanying figures, and are only intended to describe the present disclosure conveniently and for the purpose of conciseness of description of the present disclosure, but should not be interpreted as indicating or implying that a device or a component indicated by the terms must have specific locations and be constructed and manipulated according to the specific locations. Therefore, these terms shouldn't be considered as limitation to the present disclosure.

In addition, terms such as “the first” and “the second” are only for the purpose of illustration, rather than being interpreted as indicating or implying any relative importance, or implicitly indicating the number of indicated technical features. Thus, technical feature(s) restricted by “the first” or “the second” may explicitly or implicitly include one or more such technical feature(s). In the description of the present disclosure, the term “a plurality of” indicates a number of at least two, unless otherwise the term “a plurality of” is explicitly and specifically defined.

In the present disclosure, unless there is additional explicit stipulation and limitation, terms such as “mount”, “connect with each other”, “connect”, “fix”, and so on should be generalizedly interpreted, for example, “connect” may be interpreted as being fixedly connected, detachably connected, or connected integrally; “connect” can also be interpreted as being mechanically connected or electrically connected; “connect” may be further interpreted as being directly connected or indirectly connected through intermediary, or being internal communication between two components or an interaction relationship between the two components. The person of ordinary skill in the art may interpret the specific meanings of the aforementioned terms in the present disclosure according to specific conditions.

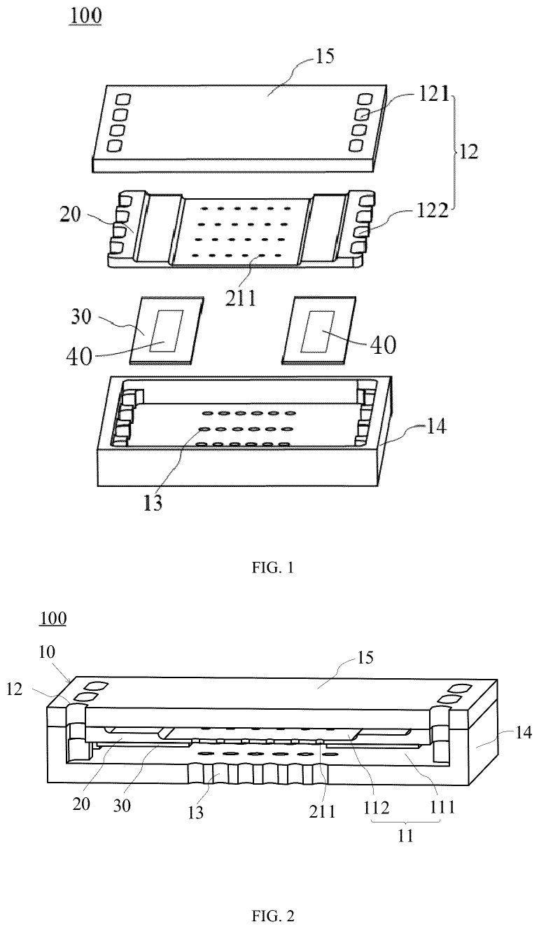

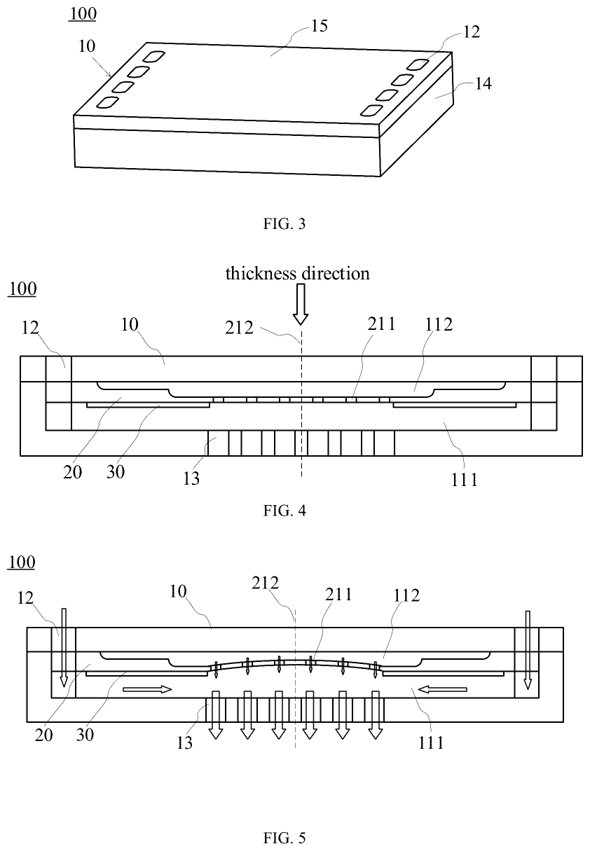

Referring to FIG. 1 to FIG. 3, one embodiment of the present disclosure provides a piezoelectric heat dissipation device 100 which includes a housing 10, an elastic sheet 20, a piezoelectric ceramic member 30, and an electric control member 40.

The housing 10 has an accommodation cavity 11, and the housing 10 is provided with an air inlet 12 and an air outlet 13 arranged to be opposite to the air inlet 12.

The housing 10 is a structure having a cavity, such as a box body, a case body. The housing 10 has an accommodation cavity 11, and the accommodation cavity 11 is configured to accommodate the elastic sheet 20 and the piezoelectric ceramic member 30.

The air inlet 12 is a through hole formed on the housing 10, and the air inlet 12 is configured to allow air to enter the accommodation cavity 11 from the outside. The number of the air inlets 12 may be one or plural, and a cross-sectional shape of the air inlet 12 is not specifically limited. For example, the cross-sectional shape of the air inlet 12 may be a circle shape, a square shape, or the like.

The air outlet 13 is a through hole formed on the housing 10, and the air outlet 13 is configured to allow air to be discharged from the accommodation cavity 11 to the outside. The number of the air outlets 13 may be one or plural, and the cross-sectional shape of the air outlet 13 is not specifically limited. For example, the cross-sectional shape of the air outlet 13 may be circle, square, or the like.

The air inlet 12 and the air outlet 13 are disposed on different end surfaces of the housing 10. For example, as shown in FIG. 1 and FIG. 2, the air inlet 12 is disposed on a top surface of the housing 10, and the air outlet 13 is disposed on a bottom surface of the housing 10. Here, the top surface and the bottom surface are corresponding orientations and positional relationships when the housing 10 is placed according to FIG. 1 and FIG. 2.

As shown in FIG. 2 and FIG. 4, the elastic sheet 20 is accommodated in the accommodation cavity 11, and two ends of the elastic sheet 20 are respectively connected to the housing 10. The elastic sheet 20 separates the accommodation cavity 11 into a first accommodation sub-cavity 111 and a second accommodation sub-cavity 112, the first accommodation sub-cavity 111 is communicated with the air outlet 13, several first nozzles 211 are provided on the elastic sheet 20, and these first nozzles 211 correspond to the air outlet 13. The elastic sheet 20 has a vibration center line 212.

The elastic sheet 20 is a sheet-like structure having a certain elasticity. The elastic sheet 20 may be a metal sheet or sheet made from other material, and the elastic sheet 20 may generate elastic deformation under the action of an external force. Specifically, the vibration center line 212 is located at a geometric center position of the elastic sheet 20.

The elastic sheet 20 is connected to a cavity wall of the accommodation cavity 11 and separates the accommodation cavity 11 into a first accommodation cavity 111 and a second accommodation sub-cavity 112. As shown in FIG. 2, the first accommodation sub-cavity 111 is a cavity structure formed by enclosing the elastic sheet 20 and the top surface of the housing 10, and the second accommodation sub-cavity 112 is a cavity structure formed by enclosing the elastic sheet 20 and the bottom surface of the housing 10.

The piezoelectric ceramic member 30 is a structure having a piezoelectric effect, the piezoelectric ceramic member 30 is deformed when an electric field or a mechanical stress is applied, and a charge distribution and a potential difference are generated accordingly.

Optionally, the piezoelectric ceramic member 30 includes a plurality of piezoelectric ceramic layers, each piezoelectric ceramic layer includes an electrode layer and a ceramic layer. The plurality of ceramic layers and the plurality of electrode layer are spaced apart from each other to form a multilayer piezoelectric ceramic member 30. The electrode layer is a conductive layer between two adjacent ceramic layers, and is usually made of a metal material, such as copper, gold, silver, or the like. The electrode layer is configured to provide an electric field for the ceramic layer to activate a piezoelectric effect. In the structure of the multilayer piezoelectric ceramic member 30, each ceramic layer has two electrodes, one electrode is arranged above the ceramic layer and one electrode is arranged below the ceramic layer. Due to this arrangement, when an external power supply applies a voltage to the two electrodes, the electric field formed between the two electrodes passes through the piezoelectric ceramic member 30, thereby resulting in the piezoelectric effect.

The piezoelectric ceramic member 30 is fixedly connected to the elastic sheet 20. For example, the piezoelectric ceramic member 30 is bonded to the elastic sheet 20. For example, the piezoelectric ceramic member 30 is welded to the elastic sheet 20.

The thickness direction of the elastic sheet 20 is the direction from the top surface of the housing 10 to the bottom surface of the housing 10 when the housing 10 is placed according to FIG. 4.

As shown in FIG. 4 to FIG. 6, the projection of the piezoelectric ceramic member 30 is in a non-overlapping relationship with the projection of the vibration center line 212 of the main part 21 in the thickness direction of the elastic sheet 20. That is, the projection of the piezoelectric ceramic member 30 does not overlap with the projection of the vibration center line 212 of the main part 21 in the thickness direction of the elastic sheet 20.

The electric control member 40 is electrically connected to the piezoelectric ceramic member 30, and the electric control member 40 is configured to supply power to the piezoelectric ceramic member 30.

The electronic control element is a structure configured to transmit an electrical signal. For example, the electric control member 40 may be a flexible printed circuit (Flexible Printed Circuit, FPC). For example, the electric control member 40 may be an elastic wire.

The electric control member 40 is electrically connected to the piezoelectric ceramic member 30, a plurality of solder joints may be arranged on the piezoelectric ceramic member 30, and the electric control member 40 is welded to the solder joints of the piezoelectric ceramic member 30, so as to achieve an electrical connection between the electric control member 40 and the piezoelectric ceramic member 30.

When the electric control member 40 supplies power to the piezoelectric ceramic member 30, current flows through the piezoelectric ceramic member 30 and generates an electric field, and the piezoelectric ceramic member 30 is deformed by being stretched or shortened under the action of the electric field. Since the piezoelectric ceramic member 30 is fixedly connected to the elastic sheet 20, the projection of the piezoelectric ceramic member 30 does not overlap with the projection of the vibration center line 212 in the thickness direction of the elastic sheet 20, and the elastic sheet 20 is further fixedly connected to the housing 10. Thus, the elastic sheet 20 is bent to be deformed under the action of the driving force of the piezoelectric ceramic member 30. In particular, the stretching deforming of the piezoelectric ceramic member 30 may be converted into up and down bending deformation of the elastic sheet 20.

As shown in FIG. 4, when the piezoelectric heat dissipation device 100 is not in operation, the electric control member 40 does not transmit an electrical signal to the piezoelectric ceramic member 30, the piezoelectric ceramic member 30 is not stretched and deformed, the elastic sheet 20 is not bent, and air in the first accommodation sub-cavity 111 and the second accommodation sub-cavity 112 does not flow.

As shown in FIG. 5, when a forward electrical signal is input to the piezoelectric ceramic member 30 through the electric control member 40, the piezoelectric ceramic member 30 drives the elastic sheet 20 to deform upwards, the volume of the second accommodation sub-cavity 112 is squeezed and reduced, the volume of the first accommodation sub-cavity 111 becomes larger, a large pressure difference is generated between the first accommodation sub-cavity 111 and the second accommodation sub-cavity 112, and the air in the second accommodation sub-cavity 112 is quickly discharged to the first accommodation sub-cavity 111 through the first nozzle 211, since the volume of the piezoelectric heat dissipation device is smaller, the speed of the air discharged from the second accommodation sub-cavity 112 will be fast, this speed is usually greater than 30 meters per second. The air has great energy when being discharged from the second accommodation sub-cavity 112, thus, the air in the first accommodation sub-cavity 111 may be driven to flow and be discharged from the air outlet 13. Meanwhile, the air outside the piezoelectric heat dissipation device 100 may flow into the first accommodation sub-cavity 111 from the air inlet 12 to realize air supply. During this process, the airflow discharged from the air outlet 13 is rapid.

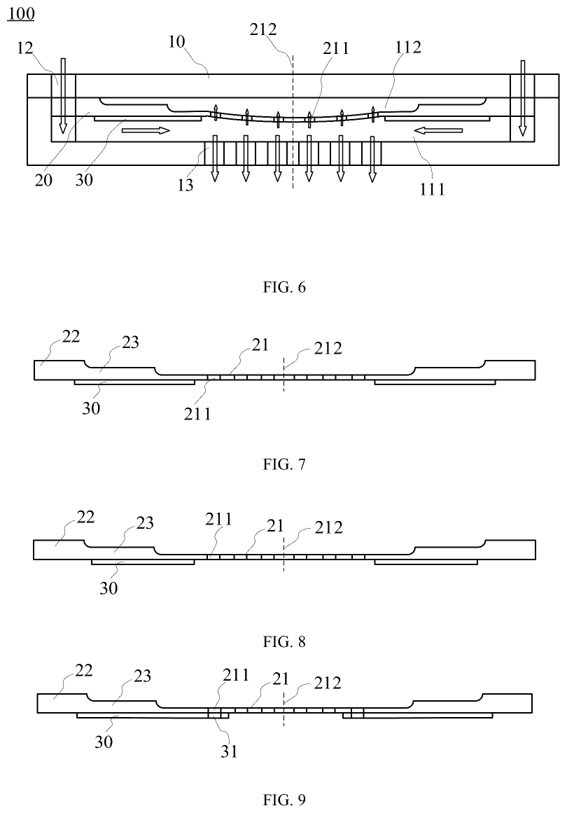

As shown in FIG. 6, when a negative electrical signal is input to the piezoelectric ceramic member 30 through the electric control member 40, the piezoelectric ceramic member 30 drives the elastic sheet 20 to deform downwards, the volume of the first accommodation sub-cavity 111 is squeezed and reduced, the volume of the second accommodation sub-cavity 112 becomes larger, a greater pressure difference between the first accommodation sub-cavity 111 and the second accommodation sub-cavity 112 is generated, the air in the first accommodation sub-cavity 111 may quickly flow into the second accommodation sub-cavity 112 through the first nozzle 211 to supplement the air flow into the second accommodation sub-cavity 112. Meanwhile, a part of the air outside the piezoelectric heat dissipation device 100 flows into the first accommodation sub-cavity 111 through toe air inlet 12 to realize air supply. The rest part of the air outside the piezoelectric heat dissipation device 100 is discharged through the air outlet 13. During this process, the air flow discharged at the air outlet 13 is slower.

According to the piezoelectric heat dissipation device 100 provided in this embodiment of the present disclosure, the electric control member 40 supplies power to the piezoelectric ceramic member 30 so as to drive the piezoelectric ceramic member 30 to be stretched and deformed, the elastic sheet 20 is driven by the piezoelectric ceramic member 30 to bend and vibrate up and down. Thus, the air in the first accommodation sub-cavity 111 and the second accommodation sub-cavity 112 flows, and the air in the accommodation cavity 11 is discharged from the air outlet 13, and new air is supplied through the air inlet 12 simultaneously to achieve the purpose of heat dissipation. The use of airflow change caused due to vibration of the piezoelectric ceramic member 30 and the vibration of the elastic sheet 20 may achieve a more miniaturized design, and provides a possibility for a micro-miniature development trend of the electronic product, and does not need a rotatable component, may reduce noise, and is conducive to providing a better user usage experience as compared to the heat dissipation device in the related art.

As shown in FIG. 1 and FIG. 4, in some embodiments, the elastic sheet 20 includes a main part 21 and two fixing parts 22 disposed at two opposite ends of the main part 21, each fixing part 22 is connected to the housing 10, and a thickness of the main part 21 is less than a thickness of the fixing part 22. the main part 21 is provided with a plurality of first nozzles 211, and the vibration center line 212 is formed at a central position of the main part 21.

It may be understood that the main part 21 is a main part of the elastic sheet 20. The main part 21 is provided with a plurality of first nozzles 211, each first nozzle 211 is configured to allow air to enter or be discharged from the second accommodation sub-cavity 112, and the first nozzle 211 corresponds to the air outlet 13, and a center line of the first nozzle 211 overlaps with a center line of the air outlet 13. The air in the second accommodation sub-cavity 112 may enter the first accommodation sub-cavity 111 through the first nozzle 211 and is discharged from the first accommodation sub-cavity 111 through the air outlet 13 to the outside of the piezoelectric heat dissipation device 100.

The thickness of the main part 21 is smaller than the thickness of the fixing part 22, when the elastic sheet 20 is stressed, the region of the vibration center line 212 of the main part 21 has the largest bending deformation amount, the other region has smaller bending deformation amount. The projection of the piezoelectric ceramic member 30 does not overlap with the projection of the vibration center line 212 of the main part 21 in the thickness direction of the elastic sheet 20, due to this arrangement, the overall bending deformation amount of the piezoelectric ceramic member 30 is smaller in the bending and deformation process of the main part 21, which is conducive to reducing the possibility of failure of the piezoelectric ceramic and improving the reliability of the piezoelectric heat dissipation device 100.

As shown in FIG. 7 and FIG. 8, in some embodiments, the projection of the piezoelectric ceramic member 30 does not overlap with the projection of each first nozzle 211 in the thickness direction of the elastic sheet 20. In the thickness direction of the elastic sheet 20, the projection of the piezoelectric ceramic member 30 does not overlap with the projection of the first nozzle 211, the piezoelectric ceramic member 30 and the first nozzle 211 are staggered, the piezoelectric ceramic member 30 does not block the first nozzle 211, and the piezoelectric ceramic member 30 does not need to be perforated, which is conducive to improving the reliability of the piezoelectric ceramic member 30 and improving the reliability of the piezoelectric heat dissipation device 100.

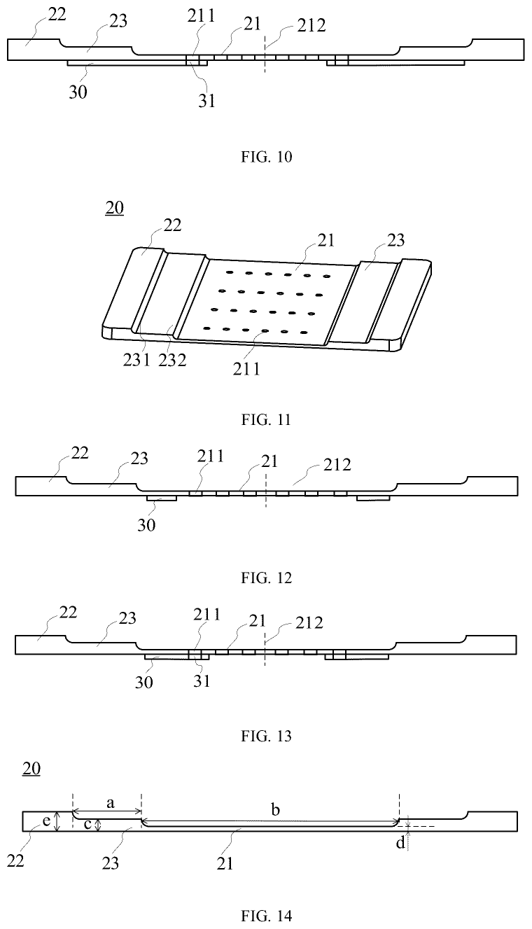

As shown in FIG. 9 and FIG. 10, in some embodiments, in the thickness direction of the elastic sheet 20, the projection of the piezoelectric ceramic member 30 overlaps with the projections of at least a part of the first nozzles 211. The projection of the piezoelectric ceramic member 30 overlaps with the projections of the first nozzles 211.

Optionally, the projection of the piezoelectric ceramic member 30 overlaps with the projections of the plurality of first nozzles 211 in the thickness direction of the elastic sheet 20, and the piezoelectric ceramic member 30 is provided with a plurality of second nozzles 31 corresponding to the part of the plurality of first nozzles 211, and the air in the second accommodation sub-cavity 112 and the air the first accommodation sub-cavity 111 may flow therebetween through the first nozzles 211 and the second nozzles 31, thereby reducing the occurrence of the condition that the piezoelectric ceramic member 30 blocks air from entering into or flowing out of the second accommodation sub-cavity 112 through the first nozzles 211.

The projection of the piezoelectric ceramic member 30 overlaps with the projections of the first nozzles 211, a contact area between the piezoelectric ceramic member 30 and the main part 21 may be increased, such that the deformation of the piezoelectric ceramic member 30 may be effectively transferred to the main part 21 to drive the main part 21 to bend to be deformed, which is conducive to improving the heat dissipation efficiency of the piezoelectric heat dissipation device 100.

As shown in FIG. 7 and FIG. 9, in some embodiments, the projection of the piezoelectric ceramic member 30 overlaps with the projection of the fixing part 22 in the thickness direction of the elastic sheet 20.

The projection of the piezoelectric ceramic member 30 overlaps with the projection of the fixing part 22, a part of the piezoelectric ceramic member 30 is connected to the fixing part 22, the other part of the piezoelectric ceramic member 30 is connected to the main part 21. When the piezoelectric ceramic member 30 is stretched and deformed, the stretching deformation of the part of the piezoelectric ceramic member 30 connected to the fixing part 22 is transmitted to the fixing part 22, thus, the fixing part 22 is driven to bend to be deformed synchronously with the bending deformation of the fixing part 22. The stretching deformation of the part of the piezoelectric ceramic member 30 connected to the main part 21 is transferred to the main part 21, thus, the main part 21 is driven to bend to be deformed synchronously with the bending deformation of the piezoelectric ceramic member 30. The thickness of the fixing part 22 is greater than the thickness of the main part 21, thus, the bending deformation of the fixing part 22 is less than the bending deformation of the main part 21, which is conducive to reducing the overall deformation of the piezoelectric ceramic member 30 when the elastic sheet 20 is bent to be deformed, reducing the failure of the piezoelectric ceramic member 30, and improving the reliability of the piezoelectric ceramic member 30.

As shown in FIG. 8 and FIG. 10, in some embodiments, the projection of the piezoelectric ceramic member 30 does not overlap with the fixing part 22 in the thickness direction of the elastic sheet 20.

The projection of the piezoelectric ceramic member 30 does not overlap with the projection of the fixing part 22, the projection of the piezoelectric ceramic member 30 only overlaps with the projection of the main part 21. Due to this arrangement, the deformation of the piezoelectric ceramic member 30 may be effectively transferred to the main part 21 to drive the main part 21 to bend to be deformed, which is conducive to improving the heat dissipation effect of the piezoelectric heat dissipation device 100.

As shown in FIG. 7, FIG. 9 and FIG. 11, in some embodiments, the elastic sheet 20 further includes a transition part 23. The transition part 23 has a first end 231 and a second end 232 which is arranged to be opposite to the first end 231. The first end 231 is connected to the fixing part 22, the second end 232 is connected to the main part 21, and the projection of the piezoelectric ceramic member 30 overlaps with the projection of the fixing part 22 in the thickness direction of the elastic sheet 20.

The projection of the piezoelectric ceramic member 30 overlaps with the projection of the fixing part 22, a part of the piezoelectric ceramic member 30 is connected to the fixing part 22, when this part of the piezoelectric ceramic member 30 is stretched to be deformed, the stretching deformation of the piezoelectric ceramic member 30 is transmitted to the fixing part 22, and the fixing part 22 is driven to bend to be deformed synchronously with the bending deformation of the piezoelectric ceramic member 30. Sine the fixing part 22 has a greater thickness, the deformation amount of the fixing part 22 is smaller, so that the deformation amount of this part of the piezoelectric ceramic member 30 is smaller, which is conducive to reducing the overall deformation of the piezoelectric ceramic, reducing the failure of the piezoelectric ceramic member 30, and improving the reliability of the piezoelectric ceramic member 30.

Optionally, as shown in FIG. 8 and FIG. 10, the projection of the piezoelectric ceramic member 30 overlaps with the projection of the transition part 23, and the projection of the piezoelectric ceramic member 30 does not overlap with the projection of the fixing part 22 in the thickness direction of the elastic sheet 20.

The projection of the piezoelectric ceramic member 30 overlaps with the projection of the transition part 23, and the projection of the piezoelectric ceramic member 30 does not overlap with the projection of the fixing part 22, the entire piezoelectric ceramic member 30 is not connected to the fixing part 22, one part of the piezoelectric ceramic member 30 is connected to the transition part 23, and the other part of the piezoelectric ceramic member 30 is connected to the main part 21. When the piezoelectric ceramic member 30 is stretched and deformed, the stretching deformation of the part of the piezoelectric ceramic member 30 connected to the transition part 23 is transferred to the transition part 23, and this part of the piezoelectric ceramic member 30 is bent to be deformed simultaneously with the bending deformation of the transition part 23. The stretching deformation of the part of the piezoelectric ceramic member 30 connected to the main part 21 is transferred to the main part 21, and this part of the piezoelectric ceramic member 30 is bent to be deformed simultaneously with the bending deformation of the main part 21. Thus, the deformation of the piezoelectric ceramic member 30 may be effectively transferred to the main part 21 to drive the main part 21 to bend to be deformed, which is conducive to improving the heat dissipation effect of the piezoelectric heat dissipation device 100.

Optionally, as shown in FIG. 12 and FIG. 13, the projection of the piezoelectric ceramic member 30 does not overlap with the projection of the transition part 23 in the thickness direction of the elastic sheet 20.

The projection of the piezoelectric ceramic member 30 does not overlap with the projection of the transition part 23, the piezoelectric ceramic member 30 is not connected to the transition part 23, the entire piezoelectric ceramic member 30 is completely connected to the main part 21. When the piezoelectric ceramic member 30 is stretched to be deformed, the energy generated by deformation may be further effectively transferred to the main part 21, and the heat dissipation effect of the piezoelectric heat dissipation device 100 is further improved.

Optionally, as shown in FIG. 12, when the projection of the piezoelectric ceramic member 30 does not overlap with the projection of the transition part 23 in the thickness direction of the elastic sheet 20, the projection of the piezoelectric ceramic member 30 does not overlap with the projections of each first nozzle 211 either. The piezoelectric ceramic member 30 and the first nozzle 211 are staggered. Thus, the piezoelectric ceramic member 30 does not block the first nozzle 211, and the piezoelectric ceramic member 30 does not need to be perforated, which is conducive to improving the reliability of the piezoelectric ceramic member 30 and improving the reliability of the piezoelectric heat dissipation device 100.

Optionally, as shown in FIG. 13, when the projection of the piezoelectric ceramic member 30 does not overlap with the projection of the transition part 23 in the thickness direction of the elastic sheet 20, the projection of the piezoelectric ceramic member 30 overlaps with the projection of each first nozzle 211, and the piezoelectric ceramic member 30 is provided with a plurality of second nozzles 31 corresponding to the first nozzles 211 so as to reduce the occurrence of blocking, by the piezoelectric ceramic member 30, air from entering or flowing out of the second accommodation sub-cavity 112 through the first nozzles 211.

As shown in FIGS. 7-10, FIG. 12 and FIG. 13, in some embodiments, the thickness of the fixing part 22 is greater than the thickness of the transition part 23, and the thickness of the transition part 23 is greater than the thickness of the main part 21.

The thicknesses of various parts of the transition part 23 may be identical.

For the elastic sheet 20, the thicker the thickness of the position of the elastic sheet 20 is, the lower the corresponding amplitude of the position of the elastic sheet 20 is, the higher the corresponding natural frequency of the position of the elastic sheet 20 is, noise is not prone to be generated at this position and the vibration amplitude of this position is smaller. The thinner the thickness of the position of the elastic sheet 20 is, the higher the corresponding amplitude of the position of the elastic sheet 20 is, the lower the corresponding natural frequency of the position of the elastic sheet 20 is, the vibration amplitude of this position is greater and noise is prone to be generated at this position. As shown in FIG. 14, in order to balance the amplitude and frequency, the noise in the operating process of the piezoelectric heat dissipation device 100 is reduced, such that the amplitude of the elastic sheet 20 is relatively high and the frequency is appropriate, a total width of the elastic sheet 20 ranges from 1 mm to 1.5 mm, a width b of the main part 21 ranges from 3 mm to 5 mm, a thickness c of the transition part 23 ranges from 0.2 mm to 0.4 mm, a thickness d of the main part 21 ranges from 0.05 mm to 0.1 mm, and a thickness e of the fixing part 22 ranges from 0.4 mm to 0.6 mm.

In some embodiments, the electric control member 40 provides an alternating current signal of 20 kHz to 25 kHz to the piezoelectric ceramic member 30, where the alternating current electric signal is in an ultrasonic range, the noise of the piezoelectric heat dissipation device 100 may be reduced.

By adopting the aforesaid technical solution, the deformation of the elastic sheet 20 may gradually transition from the main part 21 to the fixing part 22 without generating a stress concentration point at the transition part 23. Thus, the stress distribution on the elastic sheet 20 may be more uniform, which is conducive to reducing stress concentration and material fatigue of the elastic sheet 20, improving the reliability of the elastic sheet 20 and the piezoelectric ceramic member 30, and improving the reliability of the piezoelectric heat dissipation device 100.

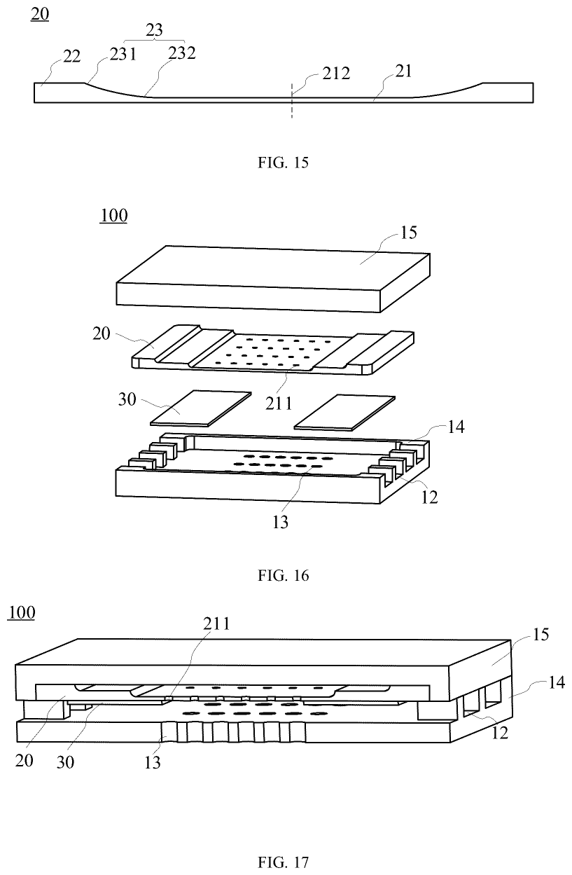

As shown in FIG. 15, in some embodiments, the thickness of the transition part 23 is progressively decreased in a direction from the first end 231 to the second end 232.

The thickness of the first end 231 of the transition part 23 is the same as the thickness of the fixing part 22, the thickness of the second end 232 is the same as the thickness of the main part 21, and the thickness of the transition part 23 smoothly and evenly transitions from the first end 231 to the second end 232.

By adopting the aforesaid technical solution, the stress concentration and the material fatigue of the elastic sheet 20 may be further reduced, the reliability of the elastic sheet 20 and the piezoelectric ceramic member 30 may be improved, and the reliability of the piezoelectric heat dissipation device 100 may be improved.

In some embodiments, a plurality of piezoelectric ceramic members 30 are provided, and the plurality of piezoelectric ceramic members 30 are symmetrically distributed at two opposite sides of the vibration center line 212.

As shown in FIG. 1, FIG. 2 and FIG. 4, two piezoelectric ceramic members 30 are provided, the two piezoelectric ceramic members 30 are arranged in the first accommodation sub-cavity 111, one piezoelectric ceramic member 30 is connected to the left side of the vibration center line 212, and the other piezoelectric ceramic member 30 is connected to the right side of the vibration center line 212. In use, current flow directions of the two piezoelectric ceramic members 30 are the same and are synchronous, and the two piezoelectric ceramics may be synchronously stretched and deformed on the two sides of the vibration center line 212, and the two opposite ends of the main part 21 drive the main part 21 to bend upwards or downwards.

By adopting the aforesaid technical solution, the plurality of piezoelectric ceramic members 30 are symmetrically arranged on two opposite sides of the vibration center line 212, more uniform vibration and higher vibration amplitude may be achieved, the air fluidity between the first accommodation sub-cavity 111 and the second accommodation sub-cavity 112 is improved, and the heat dissipation effect of the piezoelectric heat dissipation device 100 is improved.

It may be understood that the number of the elastic sheet(s) 20 is one or plural. For example, when the number of the elastic sheets 20 is one, the plurality of piezoelectric ceramic members 30 are symmetrically distributed at two opposite sides of the vibration center line 212 of the elastic sheet 20. For example, when a plurality of elastic sheets 20 are provided, the plurality of elastic sheets 20 are horizontally arranged in the accommodation cavity, and the plurality of elastic sheets 20 separate the accommodation cavity 11 into a second accommodation sub-cavity 112 and a first accommodation sub-cavity 111, the vibration center lines 212 of the plurality of elastic sheets 20 are located on the same plane, and the plurality of piezoelectric ceramic members 30 are symmetrically distributed on two opposite sides of the plane. The plurality of piezoelectric ceramics 30 may drive the plurality of elastic sheets 20 to bend to be deformed synchronously.

As shown in FIG. 1 to FIG. 6, in some embodiments, the air inlet 12 and the air outlet 13 are arranged in a staggered manner, and the air in the first accommodation sub-cavity 111 and the second accommodation sub-cavity 112 flows out from the air outlet 13 unidirectionally.

The positions of the air inlet 12 and the air outlet 13 respectively communicated with the first housing 14 and the second housing 15 are asymmetric, the air inlet 12 and the air outlet 13 are not directly and oppositely penetrated through, instead, they are arranged in a relatively staggered manner. Thus, the air may be effectively guided to enter from the air inlet 12 and is discharged from the air outlet 13. For example, as shown in FIG. 1, FIG. 2, FIGS. 4-6, the air inlet 12 is arranged on a top surface of the housing 10, the air outlet 13 is arranged on a bottom surface of the housing 10, the air inlet 12 and the air outlet 13 are arranged in a staggered manner.

When the piezoelectric heat dissipation device 100 is in operation, air always enters from the air inlet 12 and flows out from the air outlet 13.

When the piezoelectric ceramic member 30 drives the elastic sheet 20 to deform upwards, a relatively great pressure difference is quickly generated between the first accommodation sub-cavity 111 and the second accommodation sub-cavity 112, the air in the second accommodation sub-cavity 112 sequentially flows through the first nozzle 211 and drives the air in the first accommodation sub-cavity 111 to flow and quickly discharge from the air outlet 13. Meanwhile, air outside the piezoelectric heat dissipation device 100 may enter the first accommodation sub-cavity 111 from the air inlet 12 to realize air supply. As shown in FIG. 5, during this process, the air flow at the air outlet 13 is rapid.

When the piezoelectric ceramic drives the elastic sheet 20 to deform downwards, the volume of the first accommodation sub-cavity 111 is squeezed and reduced, the volume of the second accommodation sub-cavity 112 becomes larger, a greater pressure difference is generated between the first accommodation sub-cavity 111 and the second accommodation sub-cavity 112, a part of the air in the first accommodation sub-cavity 111 rapidly flows into the second accommodation sub-cavity 112 through the first nozzle 211 to supply the airflow in the second accommodation sub-cavity 112, and the remaining part of the air in the first accommodation sub-cavity 111 is discharged to the outside from the air outlet 13, as shown in FIG. 6. During this process, the airflow discharged at the air outlet 13 is relatively slow.

By adopting the aforesaid technical solution, the air inlet 12 and the air outlet 13 are arranged in a staggered manner, air may be effectively guided to enter from the air inlet 12 and be discharged from the air outlet 13, such that the air entering from the air inlet 12 is prevented from flowing out directly from the air outlet 13 when the elastic sheet 20 does not vibrate. The air flows out from the air outlet 13 unidirectionally, after being electrified, the airflow may always flow out through the air outlet 13 and does not flow back, which is conducive to improving the heat dissipation effect and the heat dissipation efficiency of the piezoelectric heat dissipation device 100.

It may be understood that the first housing 14 and the second housing 15 are adapted to each other, the second housing 15 is covered on the first housing 14, the first housing 14 and the second housing 15 may be quickly disassembled and assembled. For example, the first housing 14 and the second housing 15 may be fixedly connected by using a buckle structure. For example, the first housing 14 and the second housing 15 may be connected through bonding or welding.

The first housing 14 and the second housing 15 are enclosed to form an accommodation cavity 11. For example, a groove is formed in the first housing 14, the second housing 15 is covered on the first housing 14 to form the accommodation cavity 11. For another example, the second housing 15 is provided with a groove, the second housing 15 is covered on the first housing 14 to form the accommodation cavity 11. For another example, both the first housing 14 and the second housing 15 are provided with a groove, and the second housing 15 is covered on the first housing 14 to form the accommodation cavity 11.

The first housing 14 has a structure, such as a box body, a case body, etc.

The second housing 15 has a structure, such as a box body, a case body, etc.

As shown in FIGS. 1-6, in some embodiments, the housing 10 includes a first housing 14 and a second housing 15 covered on the first housing 14, the first housing 14 and the second housing 15 are enclosed to form an accommodation cavity 11, the fixing part 22 is connected to the first housing 14 and the second housing 15, the first housing 14 is provided with an air outlet 13, the second housing 15 is provided with an air inlet 12, and the orientation of the air inlet 12 is parallel to the orientation of the air outlet 13.

As shown in FIGS. 1-3, in some embodiments, the air inlet 12 includes a first sub-inlet 121 and a second sub-inlet 122 communicated with the first sub-inlet 121. The housing 10 is provided with the first sub-inlet 121, and the fixing part 22 is provided with the second sub-inlet 122.

By adopting the aforesaid technical solution, the first housing 14 and the second housing 15 are enclosed to form the accommodation cavity 11, the first housing 14 and the second housing 15 are covered with each other, which is conducive to realizing quick disassembly and assembly of the piezoelectric heat dissipation device 100. The elastic sheet 20 is connected in the accommodation cavity 11, which is conducive to improving the stability and the compactness of the structure of the piezoelectric heat dissipation device 100, and reducing the space occupation of the piezoelectric heat dissipation device 100. Air may enter or be discharged quickly through the first sub-inlet 121 provided on the second housing 15 and the second sub-inlet 122 provided on the elastic sheet 20, and the air outlet 13 provided on the first housing 14.

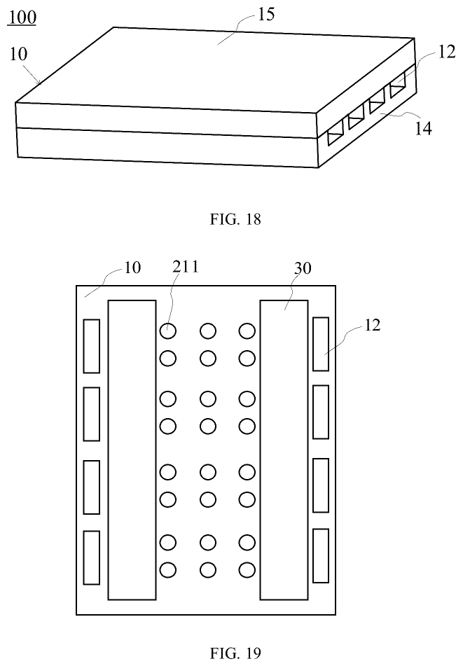

As shown in FIGS. 16-18, in some embodiments, the housing 10 includes a first housing 14 and a second housing 15 covered on the first housing 14. The first housing 14 and the second housing 15 are enclosed to form the accommodation cavity 11, the fixing part 22 is connected to the first housing 14 and the second housing 15, the first housing 14 is provided with the air outlet 13 and the air inlet 12, and the orientation of the air inlet 12 is perpendicular to the orientation of the air outlet 13.

Specifically, the fixing part 22 is connected to the first housing 14 and the second housing 15, the first housing 14 is provided with the air outlet 13, the orientation of the air outlet 13 is a vertical direction. The first housing 14 is provided with the air inlet 12, the orientation of the air inlet 12 is a horizontal direction, and the orientation of the air inlet 12 is perpendicular to the orientation of the air outlet 13. Then, air may enter or be discharged quickly through the air inlet 12 provided on the second housing 15 and the air outlet 13 provided on the first housing 14.

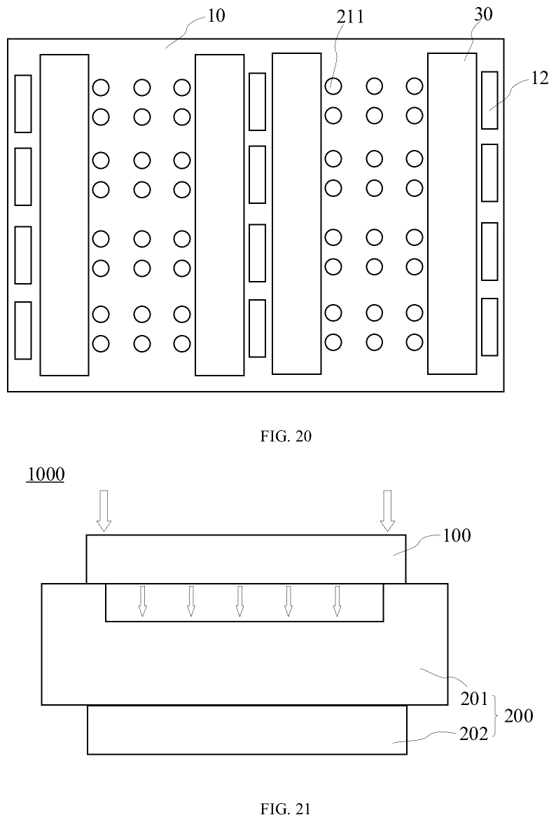

In some embodiments, the number and the size of the housing 10, the elastic sheet 20, the piezoelectric ceramic member 30, the air inlet 12, the air outlet 13, and the first nozzle(s) 211 in the piezoelectric heat dissipation device 100 may be changed according to actual usage requirement. Exemplarily, as shown in FIG. 19, when the piezoelectric heat dissipation device 100 extends and expands in the longitudinal direction, the numbers of the air inlet 12, the air outlet 13, and the first nozzle(s) 211 may be correspondingly increased, and the sizes of the housing 10, the elastic sheet 20, and the piezoelectric ceramic member 30 may be correspondingly increased. Exemplarily, as shown in FIG. 20, when the piezoelectric heat dissipation device 100 extends and expands in the transverse direction, the numbers of the air inlet 12, the air outlet 13, the piezoelectric ceramic member 30 and the first nozzle 211 may be correspondingly increased, and the sizes of the housing 10, the elastic sheet 20 and the piezoelectric ceramic member 30 may be correspondingly increased.

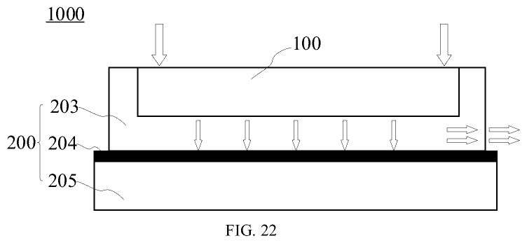

As shown in FIG. 21 and FIG. 22, an electronic device 1000 is further provided in the present disclosure. The electronic device 1000 includes a heat dissipation member 200, and further includes the aforesaid piezoelectric heat dissipation device 100, where the heat dissipation member 200 is disposed at the air outlet 13.

The electronic device 1000 may be a device having a heat dissipation requirement, such as a mobile phone, a computer, a tablet computer, and a game handle.

The heat dissipation member 200 is a structure that needs heat dissipation in the electronic device 1000.

The heat dissipation member 200 is disposed at the air outlet 13, and air in the piezoelectric heat dissipation device 100 is discharged through the air outlet 13 and performs heat dissipation on the heat dissipation member 200.

For example, as shown in FIG. 21, the heat dissipation member 200 includes a ceramic substrate 201 and an electronic component 202, the ceramic substrate 201 and the electronic component 202 are disposed at the air outlet 13 of the piezoelectric heat dissipation device 100. Air in the piezoelectric heat dissipation device 100 is discharged from the air outlet 13 and performs heat dissipation on the ceramic substrate 201 and the electronic component 202.

For example, as shown in FIG. 22, the heat dissipation member 200 includes a supporting structure 203, a heat conduction member 204 and a heat dissipation submember 205. The heat conduction member 204 may be a structure such as a heat conduction silicone grease, heat conduction silica gel, and a heat conduction gasket. The heat dissipation submember 205 may be a structure such as a heat dissipation pipe, a soaking plate, and a heat dissipation plate. The supporting structure 203, the heat conduction member 204 and the heat dissipation submember 205 are arranged at the air outlet 13 of the piezoelectric heat dissipation device 100, and the air in the piezoelectric heat dissipation device 100 is discharged through the air outlet 13 so as to perform heat dissipation on the supporting structure 203, the heat conduction member 204 and the heat dissipation submember 205.

In the electronic device 1000 provided in this embodiment of the present disclosure, when the heat dissipation member 200 is disposed at the air outlet 13 of the piezoelectric heat dissipation device 100, when the piezoelectric heat dissipation device 100 is in operation, the electric control member 40 supplies power to the piezoelectric ceramic member 30 to drive the piezoelectric ceramic member 30 to be stretched and deformed. The main part 21 of the elastic sheet 20 is driven by the piezoelectric ceramic member 30 to bend and vibrate up and down, such that the air in the first accommodation sub-cavity 111 and the second accommodation sub-cavity 112 is discharged from the air outlet 13, and new air is supplied from the air inlet 12 simultaneously to achieve the purpose of heat dissipation. The thickness of the main part 21 is smaller than the thickness of the fixing part 22, when the elastic sheet 20 is stressed, the region of the vibration center line 212 of the main part 21 has the greatest bending deformation amount, the other region has smaller bending deformation amount. In the thickness direction of the elastic sheet 20, the projection of the piezoelectric ceramic member 30 does not overlap with the projection of the vibration center line 212 of the main part 21. Due to this arrangement, the overall bending deformation amount of the piezoelectric ceramic member is smaller in the bending deformation process of the main part, which is conducive to reducing the possibility of failure of the piezoelectric ceramic and improving the reliability of the piezoelectric heat dissipation device.

The foregoing embodiments are only preferable embodiments of the present disclosure, and should not be regarded as limitations to the present disclosure. All modifications, equivalent replacements, and improvements, which are made within the spirit and the principle of the present disclosure, should all be included in the protection scope of the present disclosure.

What is claimed is:

1. A piezoelectric heat dissipation device, comprising:
a housing, wherein the housing has an accommodation cavity and is provided with an air inlet and an air outlet;
an elastic sheet, wherein the elastic sheet is accommodated in the accommodation cavity, and two opposite ends of the elastic sheet are respectively connected with the housing, the elastic sheet is configured to divide the accommodation cavity into a first accommodation sub-cavity and a second accommodation sub-cavity, the first accommodation sub-cavity is connected with the air outlet, a plurality of first nozzles are provided on the elastic sheet and correspond to the air outlet, and the elastic sheet has a vibration center line;
a piezoelectric ceramic member, wherein the piezoelectric ceramic member is fixedly connected to the elastic sheet, and a projection of the piezoelectric ceramic member does not overlap with a projection of the vibration center line in a thickness direction of the elastic sheet; and
an electric control member electrically connected with the piezoelectric ceramic member, wherein the electric control member is configured to supply power to the piezoelectric ceramic member.

2. The piezoelectric heat dissipation device according to claim 1, wherein the elastic sheet has a symmetrical structure, the elastic sheet comprises a main part and two fixing parts arranged at two opposite ends of the main part, each fixing part is connected to the housing, and a thickness of the main part is less than a thickness of the fixing part; the main part is provided with the plurality of first nozzles, and the vibration center line is an axis of symmetry of the main part.

3. The piezoelectric heat dissipation device according to claim 2, wherein the projection of the piezoelectric ceramic member does not overlap with a projection of each first nozzle in the thickness direction of the elastic sheet; or alternatively,
the projection of the piezoelectric ceramic member overlaps with the projection of the first nozzle in the thickness direction of the elastic sheet.

4. The piezoelectric heat dissipation device according to claim 3, wherein the projection of the piezoelectric ceramic member overlaps with projections of at least a part of the plurality of first nozzles in the thickness direction of the elastic sheet, and the piezoelectric ceramic member is provided with a plurality of second nozzles corresponding to this part of the plurality of first nozzles.

5. The piezoelectric heat dissipation device according to claim 3, wherein the projection of the piezoelectric ceramic member overlaps with a projection of the fixing part in the thickness direction of the elastic sheet; or alternatively,
the projection of the piezoelectric ceramic member does not overlap with the projection of the fixing part in the thickness direction of the elastic sheet.

6. The piezoelectric heat dissipation device according to claim 3, wherein the elastic sheet further comprises a transition part, the transition part comprises a first end and a second end which are oppositely arranged, the first end is connected to the two fixing parts, and the second end is connected to the main part; the projection of the piezoelectric ceramic member overlaps with the projection of the fixing part in the thickness direction of the elastic sheet; or alternatively,
the projection of the piezoelectric ceramic member overlaps with a projection of the transition part and the projection of the piezoelectric ceramic member does not overlap with the projection of the fixing part in the thickness direction of the elastic sheet; or alternatively,
the projection of the piezoelectric ceramic member does not overlap with the projection of the transition part in the thickness direction of the elastic sheet.

7. The piezoelectric heat dissipation device according to claim 6, wherein a thickness of the fixing part is greater than a thickness of the transition part, and the thickness of the transition part is greater than a thickness of the main part.

8. The piezoelectric heat dissipation device according to claim 7, wherein the thickness of the transition part is progressively decreased in a direction from the first end to the second end.

9. The piezoelectric heat dissipation device according to claim 3, wherein a plurality of piezoelectric ceramic members are provided, and the plurality of piezoelectric ceramic members are symmetrically distributed on two opposite sides of the vibration center line.

10. The piezoelectric heat dissipation device according to claim 2, wherein the air inlet and the air outlet are arranged in a staggered manner, and air in the first accommodation sub-cavity and air the second accommodation sub-cavity are discharged unidirectionally through the air outlet.

11. The piezoelectric heat dissipation device according to claim 10, wherein the housing comprises a first housing and a second housing covered on the first housing, the first housing and the second housing are enclosed to form the accommodation cavity, and the two fixing parts are respectively connected to the first housing and the second housing;
the air outlet is provided on the first housing, the air inlet is provided on the second housing, and an orientation of the air inlet is parallel to an orientation of the air outlet; or alternatively,
the air outlet and the air inlet are provided on the first housing, and the orientation of the air inlet is perpendicular to the orientation of the air outlet.

12. The piezoelectric heat dissipation device according to claim 11, wherein the air outlet and the air inlet are provided on the first housing, and the orientation of the air inlet is parallel to the orientation of the air outlet; and the air inlet comprises a first sub-inlet and a second sub-inlet communicated with the first sub-inlet, wherein the first sub-inlet is provided on the second housing, and the second sub-inlet is provided on the fixing part.

13. An electronic device, comprising a heat dissipation member and a piezoelectric heat dissipation device, the piezoelectric heat dissipation device comprising:
a housing, wherein the housing has an accommodation cavity and is provided with an air inlet and an air outlet;
an elastic sheet, wherein the elastic sheet is accommodated in the accommodation cavity, and two opposite ends of the elastic sheet are respectively connected with the housing, the elastic sheet is configured to divide the accommodation cavity into a first accommodation sub-cavity and a second accommodation sub-cavity, the first accommodation sub-cavity is connected with the air outlet, a plurality of first nozzles are provided on the elastic sheet and correspond to the air outlet, and the elastic sheet has a vibration center line;
a piezoelectric ceramic member, wherein the piezoelectric ceramic member is fixedly connected to the elastic sheet, and a projection of the piezoelectric ceramic member does not overlap with a projection of the vibration center line in a thickness direction of the elastic sheet; and
an electric control member electrically connected with the piezoelectric ceramic member, wherein the electric control member is configured to supply power to the piezoelectric ceramic member;
wherein the heat dissipation member is disposed at the air outlet.

14. The electronic device according to claim 13, wherein the elastic sheet has a symmetrical structure, the elastic sheet comprises a main part and two fixing parts arranged at two opposite ends of the main part, each fixing part is connected to the housing, and a thickness of the main part is less than a thickness of the fixing part; the main part is provided with the plurality of first nozzles, and the vibration center line is an axis of symmetry of the main part.

15. The electronic device according to claim 14, wherein the projection of the piezoelectric ceramic member does not overlap with a projection of each first nozzle in the thickness direction of the elastic sheet; or alternatively,
the projection of the piezoelectric ceramic member overlaps with the projection of the first nozzle in the thickness direction of the elastic sheet.

16. The electronic device according to claim 15, wherein the projection of the piezoelectric ceramic member overlaps with projections of at least a part of the plurality of first nozzles in the thickness direction of the elastic sheet, and the piezoelectric ceramic member is provided with a plurality of second nozzles corresponding to this part of the plurality of first nozzles.

17. The electronic device according to claim 15, wherein the projection of the piezoelectric ceramic member overlaps with a projection of the fixing part in the thickness direction of the elastic sheet; or alternatively,
the projection of the piezoelectric ceramic member does not overlap with the projection of the fixing part in the thickness direction of the elastic sheet.

18. The electronic device according to claim 15, wherein the elastic sheet further comprises a transition part, the transition part comprises a first end and a second end which are oppositely arranged, the first end is connected to the two fixing parts, and the second end is connected to the main part; the projection of the piezoelectric ceramic member overlaps with the projection of the fixing part in the thickness direction of the elastic sheet; or alternatively,
the projection of the piezoelectric ceramic member overlaps with a projection of the transition part and the projection of the piezoelectric ceramic member does not overlap with the projection of the fixing part in the thickness direction of the elastic sheet; or alternatively,
the projection of the piezoelectric ceramic member does not overlap with the projection of the transition part in the thickness direction of the elastic sheet.

19. The electronic device according to claim 18, wherein a thickness of the fixing part is greater than a thickness of the transition part, and the thickness of the transition part is greater than a thickness of the main part.

20. The electronic device according to claim 19, wherein the thickness of the transition part is progressively decreased in a direction from the first end to the second end.
